(19) United States
(12) Patent Application Publication
(10) Pub. No.: US 2006/0003536 A1
(43) Pub. Date: Jan. 5, 2006

(54) Method for fabricating a trench capacitor with an insulation collar which is electrically connected to a substrate on one side via a buried contact, in particular for a semiconductor memory cell

(76) Inventor: Stephan Kudelka, Dresden (DE)

Correspondence Address: JENKINS, WILSON & TAYLOR, P. A., 3100 TOWER BLVD, SUITE 1400, DURHAM, NC, 27707, US

(21) Appl. No.: 11/152,968

(22) Filed: Jun. 15, 2005

(30) Foreign Application Priority Data
Jun. 30, 2004 (DE) 102004031694.5

(51) Int. Cl. H01L 21/76; H01L 21/20

(52) U.S. Cl. 438/386

(57) ABSTRACT

The present invention provides a method for fabricating a trench capacitor with an insulation collar (10) in a substrate (1), which is electrically connected to the substrate (1) on one side via a buried contact, having the steps of: providing a trench (5) in the substrate (1) using a hard mask (2, 3) with a corresponding mask opening; providing a capacitor dielectric (30) in the lower and central trench region, the insulation collar (10) in the central and upper trench region and an electrically conductive filling (20) as far as the top side of the insulation collar (10); providing a spacer (21′) made of a conductive material above the insulation collar (10) in electrical contact with the substrate (1); completely filling the trench (5) with a filling material (23; 50) above the liner layer (22; 40); carrying out an STI trench fabrication process; removing the filling material (23; 50) and sinking the electrically conductive filling (20) to below the top side of the insulation collar (10); providing a metallic filling (25) in the trench (5) and etching back the metallic filling (25) as far as the top side of the spacer (21′); and providing an insulation region (IS) on one side and a contact region (KS) on a different side with respect to the substrate (1) above the insulation collar (10) by partly removing the spacer (21′).

The present invention provides a method for fabricating a trench capacitor with an insulation collar which is electrically connected to a substrate on one side via a buried contact, in particular for a semiconductor memory cell.

Although applicable in principle to any desired integrated circuits, the present invention and the problem area on which it is based are explained with regard to integrated memory circuits in silicon technology.

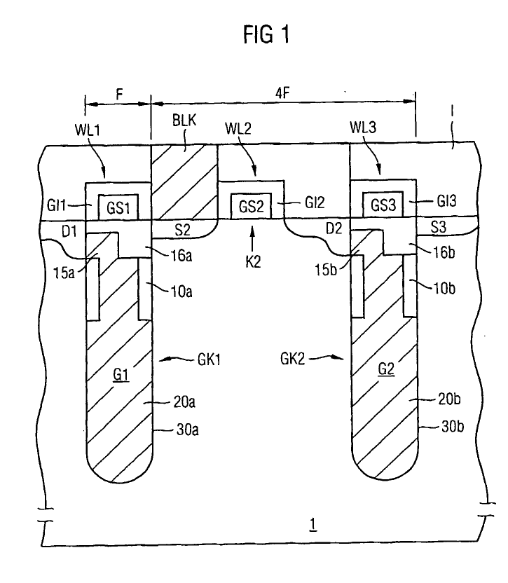

FIG. 1 shows a diagrammatic sectional illustration of a semiconductor memory cell with a trench capacitor and a planar selection transistor connected thereto.

In FIG. 1, reference symbol 1 designates a silicon semiconductor substrate. Provided in the semiconductor substrate 1 are trench capacitors GK1, GK2 having trenches G1, G2, the electrically conductive fillings 20a, 20b of which form first capacitor electrodes. The conductive fillings 20a, 20b are insulated in the lower and central trench region by a dielectric 30a, 30b from the semiconductor substrate 1, which, for its part, forms the second capacitor electrodes (if appropriate in the form of a buried plate (not shown)).

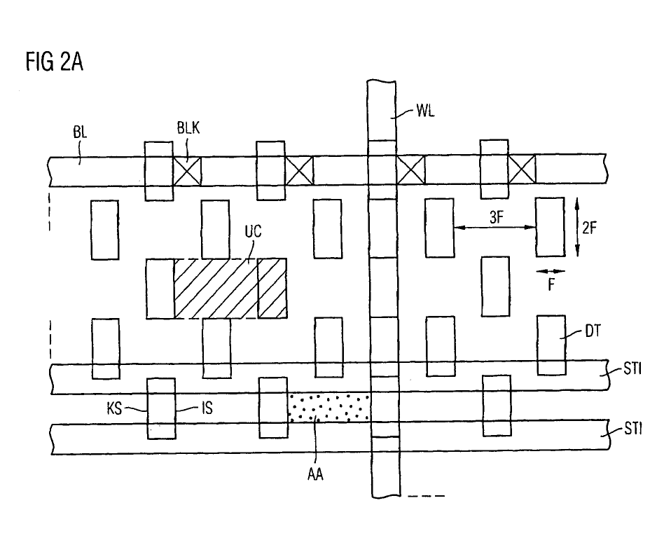

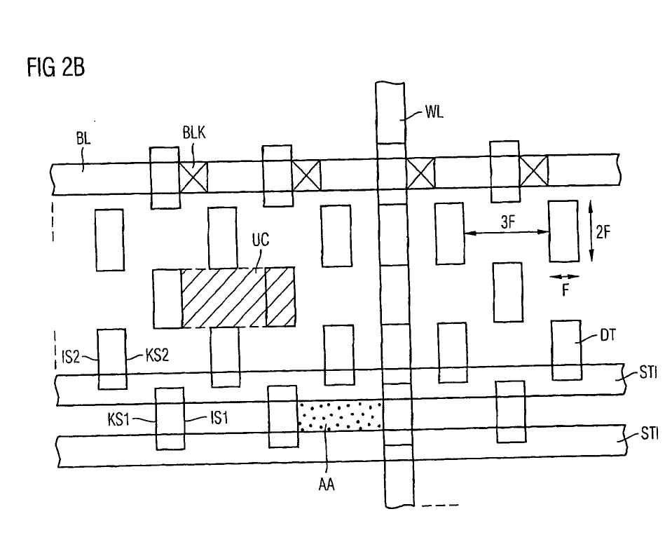

Provided in the central and upper region of the trenches G1, G2 are peripheral insulation collars 10a, 10b, above which are provided buried contacts 15a, 15b, which are in electrical contact with the conductive fillings 20a, 20b and the adjoining semiconductor substrate 1. The buried contacts 15a, 15b are connected to the semiconductor substrate 1 only on one side (cf. FIGS. 2a, b). Insulation regions 16a, 16b insulate the other side of the substrate from the buried contacts 15a, 15b or insulate the buried contacts 15a, 15b toward the top side of the trenches G1, G2.

This enables a very high packing density of the trench capacitors GK1, GK2 and of the associated selection transistors, which will now be explained. In this case, reference is made principally to the selection transistor which is associated with the trench capacitor GK2, since only the drain region D1 or the source region S3, respectively, of adjacent selection transistors is depicted. The selection transistor associated with the trench capacitor GK2 has a source region S2, a channel region K2 and a drain region D2. The source region S2 is connected via a bit line contact BLK to a bit line (not shown) arranged above an insulation layer I. The drain region D2 is connected to the buried contact 15b on one side. A word line WL2 having a gate stack GS2 and a gate insulator GI2 surrounding the latter runs above the channel region K2. The word line WL2 is an active word line for the selection transistor of the trench capacitor GK2.

Running parallel adjacent to the word line WL2 are word lines WL1 comprising gate stack GS1 and gate insulator GIl and word line WL3 comprising gate stack GS3 and gate insulator GI3, which are passive word lines for the selection transistor of the trench capacitor GK2. Said word lines WL1, WL3 serve for driving selection transistors which are displaced in the third dimension with respect to the sectional illustration shown.

FIG. 1 illustrates the fact that this type of connection on one side of the buried contact enables the trenches and the adjacent source regions or drain regions of relevant selection transistors to be arranged directly beside one another. As a result, the length of a memory cell may amount to just 4 F and the width to just 2 F, where F is the minimum length unit that can be realized technologically (cf. FIGS. 2a, b).

FIG. 2A shows a plan view of a memory cell array with memory cells in accordance with FIG. 1 in a first arrangement possibility.

Reference symbol DT in FIG. 2A designates trenches which are arranged row-wise at a distance of 3 F from one another and columnwise at a distance of 2 F. Adjacent rows are displaced by 2 F relative to one another. UC in FIG. 2A designates the area of a unit cell, which amounts to 4 F×2 F=8 F². STI designates isolation trenches which are arranged at a distance of 1 F from one another in the row direction and insulate adjacent active regions from one another. Bit lines BL likewise run at a distance of 1 F from one another in the row direction, whereas the word lines run at a distance of 1 F from one another in the column direction. In this arrangement example, all the trenches DT have a contact region KS of the buried contact to the substrate on the left-hand side and an insulation region IS on the right-hand side (regions 15a, b and 16a, b, respectively, in FIG. 1).

FIG. 2B shows a plan view of a memory cell array with memory cells in accordance with FIG. 1 in a second arrangement possibility.

In this second arrangement possibility, the rows of trenches have alternating connection regions and insulation regions of the buried contacts, respectively. Thus, in the bottommost row of FIG. 2B, the buried contacts are in each case provided with a contact region KS1 on the left-hand side and with an insulation region IS1 on the right-hand side. By contrast, in the row located above that, all the trenches DT are provided with each insulation region IS2 on the left-hand side and with a contact region KS2 on the right-hand side. This arrangement alternates in the column direction.

For DRAM memory devices with trench capacitors in sub-100 nm technologies, the resistance of the trench and of the buried contact are a main contribution to the total RC delay, and thus determine the speed of the DRAM. The relatively low conductivity and the pinch-off, which is produced by an overlay displacement of the STI etching, results in a dramatic increase in the series resistance in the trench.

This problem has been tackled by introducing polysilicon that is highly doped with arsenic, improving the overlay between the active regions and the trench, introducing self-aligned fabrication of a buried contact with a connection on one side and thinning the nitrided contact point of the buried contact. In particular, the upper region of the polysilicon filling that is highly doped with arsenic in the trench forms a major problem for sub-100 nm technologies since the degree of doping cannot be increased further and the diameter is influenced by the STI trench formation (ST=Shallow Trench Isolation).

The object of the present invention is to specify an improved method for fabricating a trench capacitor connected on one side and having a shorter RC delay.

According to the invention, this object is achieved by means of the fabrication method specified in Claim 1. The central idea of the present invention exists in providing a process in which a metallic, oxidation-sensitive buried contact, in conjunction with a polysilicon spacer provided at the interface with the substrate, can be used in order to reduce the contact resistance. The metal filling and etching-back after the STI formation (STI=shallow trench isolation) is in particular integrated into the method according to the invention and thus enables the formation of a functional buried metallic contact region connected on one side in the trench.

Advantageous developments and improvements of the fabrication method specified in Claim 1 are found in the subclaims.

In accordance with one preferred development, a liner layer is provided in the trench before the trench is filled, and the liner layer is likewise removed after the removal of the filling material.

In accordance with a further preferred development, after the metallic filling has been etched back, an insulation cover is provided in the upper trench region at least as far as the top side of the substrate.

In accordance with a further preferred development, the spacer is provided after the removal of the filling material and, before the spacer is provided, a further spacer is formed on the trench walls above the insulation collar, which serves as a mask in the course of sinking the electrically conductive filling and is then removed.

In accordance with a further preferred development, the following steps are carried out for partly removing the spacer: providing a liner layer in the trench; providing a mask on the liner layer in the trench, which has an opening above the spacer region to be removed; perforating the liner layer and selectively removing the spacer region to be removed using the mask.

In accordance with a further preferred development, the spacer is provided by depositing a liner layer made of the conductive material and carrying out a spacer etching.

In accordance with a further preferred development, the spacer is provided before the trench is filled.

In accordance with a further preferred development, the metallic filling comprises TiN or W or WSix or TaN or WN or HfN. Preferably, TiN is proposed as a metal filling owing to its superior thermal stability in contact with Si and SiO₂.

In accordance with a further preferred development, the conductive material is polysilicon.

In accordance with a further preferred development, the liner layer comprises silicon nitride.

Exemplary embodiments of the invention are illustrated in the drawings and explained in more detail in the description below.

In the figures:

FIG. 1 shows a diagrammatic sectional illustration of a semiconductor memory cell with a trench capacitor and a planar selection transistor connected thereto;

FIGS. 2A,B show a respective plan view of a memory cell array with memory cells in accordance with FIG. 1 in a first and second arrangement possibility;

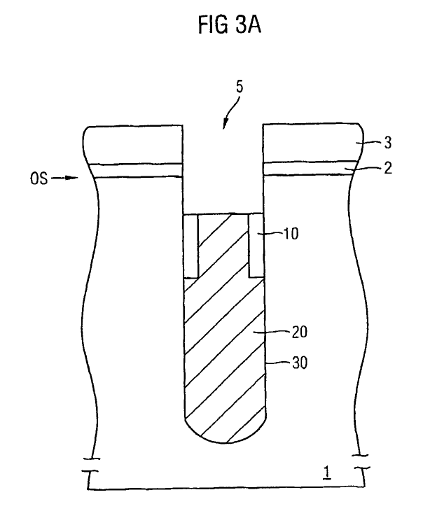

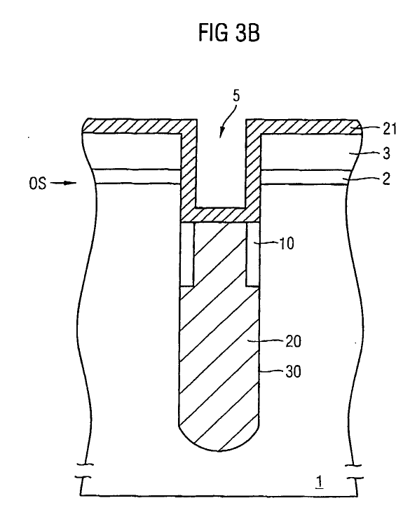

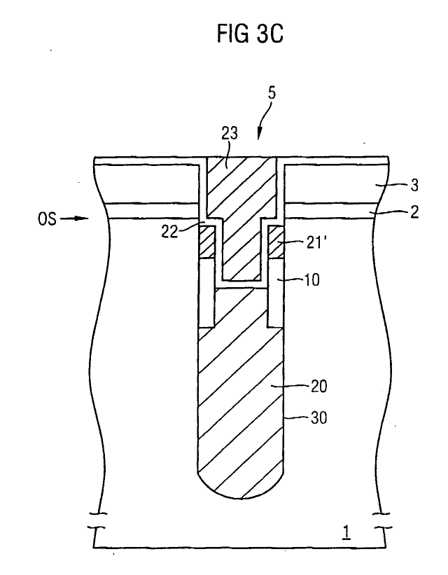

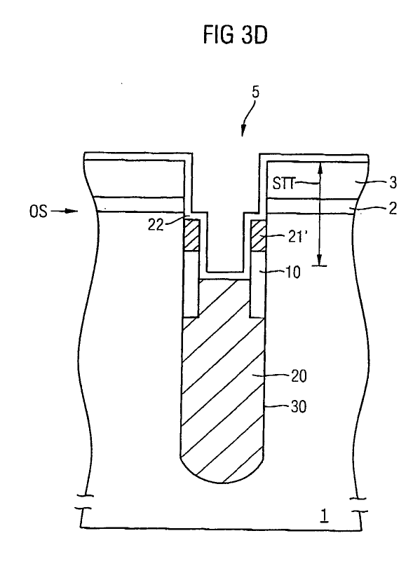

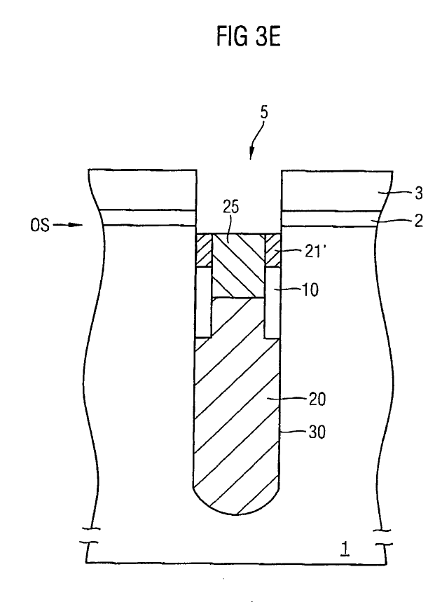

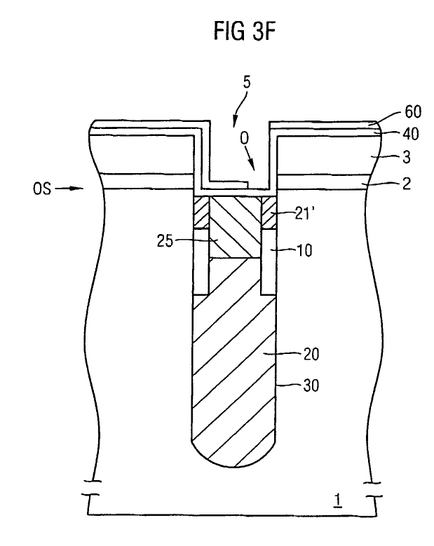

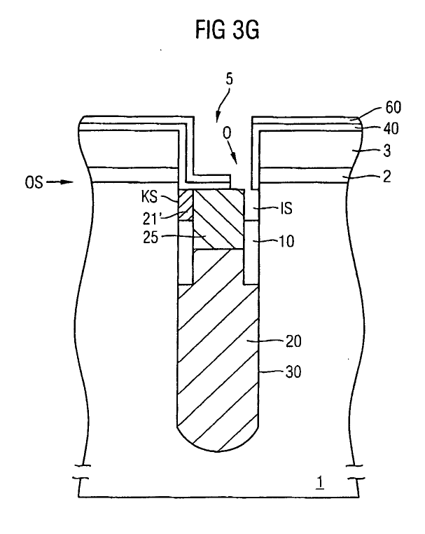

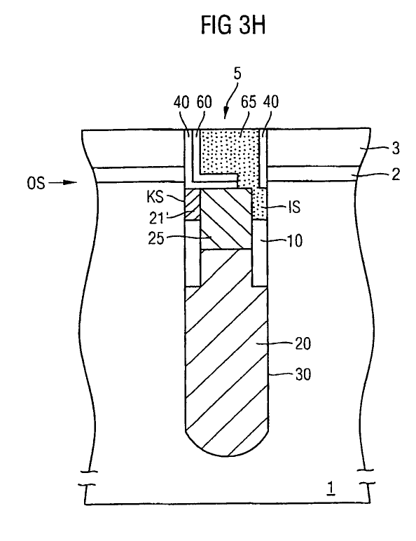

FIGS. 3A-H show diagrammatic illustrations of successive method stages of a fabrication method as first embodiment of the present invention; and

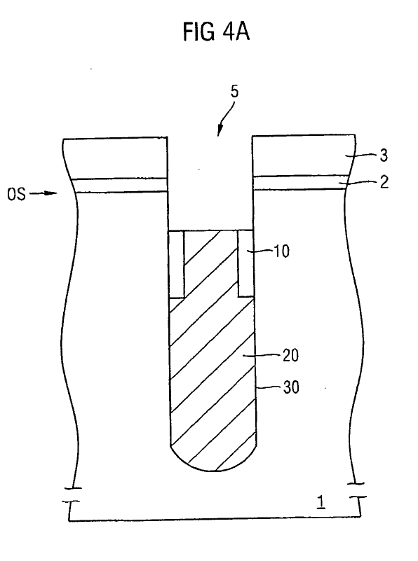

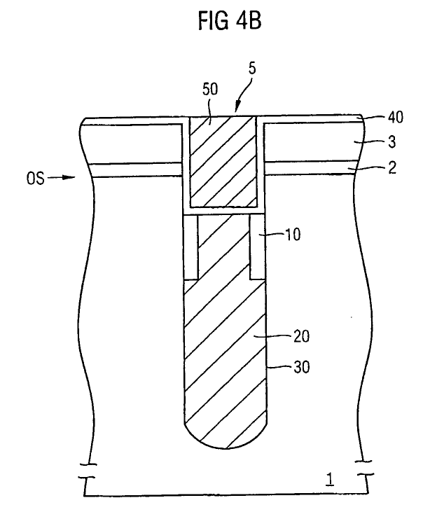

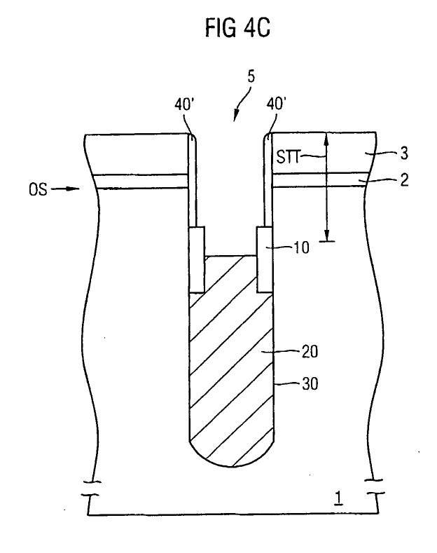

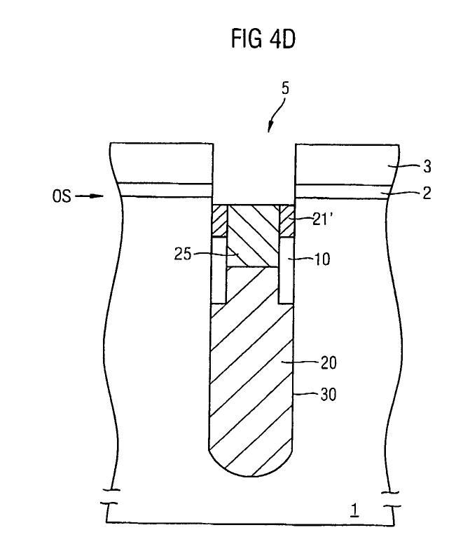

FIGS. 4A-D show diagrammatic illustrations of successive method stages of a fabrication method as second embodiment of the present invention.

In the figures, identical reference symbols designate identical or functionally identical constituent parts.

In the embodiments described below, for reasons of clarity, a portrayal of the fabrication of the planar selection transistors is dispensed with and only the formation of the buried contact of the trench capacitor, which buried contact is connected on one side, is discussed in detail. Unless expressly mentioned otherwise, the steps of fabricating the planar selection transistors are the same as in the prior art.

FIGS. 3A-H are diagrammatic illustrations of successive method stages of a fabrication method as first embodiment of the present invention.

In FIG. 3A, reference symbol 5 designates a trench provided in the silicon semiconductor substrate 1. Provided on the top side OS of the semiconductor substrate 1 is a hard mask comprising a pad oxide layer 2 and a pad nitride layer 3. A dielectric 30 is provided in the lower and central region of the trench 5, said dielectric insulating an electrically conductive filling 20 from the surrounding semiconductor substrate 1.

A peripheral insulation collar 10 is provided in the upper and central region of the trench 5, said insulation collar being sunk into the trench 5 to approximately the same level as the conductive filling 20. An exemplary material for the insulation collar 10 is silicon oxide, and polysilicon for the electrically conductive filling 20. However, other material combinations are also conceivable, of course.

In accordance with FIG. 3B, firstly a liner layer 21 is deposited above the structure in accordance with FIG. 3A, which comprises silicon, in particular polysilicon. A nitriding for conditioning the substrate surface may also be carried out beforehand, if desired.

A spacer etching is thereupon carried out in accordance with FIG. 3C in order to convert the silicon liner 21 to a silicon spacer 21′. In a subsequent process step, a silicon nitride liner layer 22 is deposited above the structure and the upper region of the trench 5 is subsequently filled with a polysilicon filling, which is polished back as far as the top side of the silicon nitride liner layer 22. In a subsequent process step, not illustrated in the figures, a hard mask is then formed above the structure in accordance with STI trenches to be formed which lie in parallel planes in front of and behind the plane of the drawing, whereupon the STI trenches are etched and filled (high-temperature process). Afterward, the hard mask for the STI trench formation is removed again.

The purpose of this advanced high-temperature step is to prevent the high-temperature step from having any further influence later than the metallic buried contact that is then to be formed.

Furthermore, with reference to FIG. 3D, in which STT designates the STI trench depth, the polysilicon filling 23 is then removed by means of a wet etching. As can be seen in FIG. 3D, the STI trench depth STT lies between the top side of the insulation collar 10 and the top side of the trench polysilicon filling 20.

Furthermore, with reference to FIG. 3E, in a subsequent process step, the silicon nitride liner layer 22 is removed and this is followed by a deposition and etching back e.g. in a chlorine-containing plasma, of a conductive TiN filling 25 in order to form the buried contact, which is still connected on all sides in this process stage. W, WSix, TaN, WN or HfN could also be used instead of TiN.

Furthermore, with reference to FIG. 3F, over the resulting structure firstly a silicon nitride liner layer 40 is then deposited and over that a silicon oxide hard mask 60. The silicon oxide hard mask 60 has an opening O in a region in which the polysilicon spacer 21′ is to be removed later, namely in accordance with a later insulation region where the trench filling is intended not to be connected to the semiconductor substrate 1.

The fabrication of the silicon oxide hard mask 60 may be effected for example by deposition of a silicon liner layer, subsequent shaded implantation of boron ions, selective removal of the shaded region by etching in accordance with the opening O and oxidation of the silicon liner layer.

In accordance with FIG. 3G, the silicon nitride liner layer 40 is then perforated in the region of the opening by means of a further etching step and a partial region of the polysilicon spacer 21′ is subsequently removed selectively in accordance with the later insulation region IS.

In a concluding process step shown in FIG. 3H, a silicon oxide filling 65 is then deposited and polished back as far as the top side of the pad nitride 3. As can be seen from FIG. 3H, the metallic TiN filling 25 is then connected to the semiconductor substrate 1 in the connection region KS, whereas it is insulated from the semiconductor substrate 1 in the insulation region IS. W, WSix, TaN, WN or HfN could also be used instead of TiN.

FIG. 4A-D are diagrammatic illustrations of successive method stages of a fabrication method as a second embodiment of the present invention.

The starting point of the second embodiment in accordance with FIG. 4A corresponds to the starting point of the first embodiment in accordance with FIG. 3A.

Then, in accordance with FIG. 4B, a silicon nitride liner layer 40 is deposited above the resulting structure and the trench 5 is subsequently closed with a polysilicon filling 50, which is polished back as far as the top side of the silicon nitride liner layer 40.

There then takes place in the same way as already explained with reference to the first embodiment, subsequently (not illustrated) the formation of the hard mask for the STI trench, the etching and filling of the STI trenches and the removal of the corresponding hard mask.

With reference to FIG. 4C, the polysilicon filling 50 is then removed. A spacer etching of the silicon nitride liner layer 40 is then effected in order to convert said layer into a silicon nitride spacer 40′. The polysilicon filling 20 in the trench 5 is subsequently etched back to below the top side of the insulation collar 10, the silicon nitride spacer 40′ masking the substrate 1 in the upper trench region.

Furthermore, with reference to FIG. 4D, firstly the silicon nitride spacer 40′ is removed by means of an etching process. This is followed by the deposition of a silicon liner 21 analogously to the first embodiment explained above into a polysilicon spacer 21′. Furthermore, as already described in the case of the first embodiment above, the TiN filling 25 is then provided in the trench 5 and etched back as far as the top side of the polysilicon spacer 21′. W, WSix, TaN, WN or HfN could also be used instead of TiN.

The process steps subsequent to FIG. 4D in the case of the second embodiment correspond to the process steps in accordance with FIG. 3F to 3H that have already been explained above.

Although the present invention has been described above on the basis of a preferred exemplary embodiment, it is not restricted thereto but rather can be modified in diverse ways.

In particular, the selection of the layer materials is only by way of example and can be varied in many different ways.

### LIST OF REFERENCE SYMBOLS

1 Si semiconductor substrate
OS Top side
2 Pad oxide
3 Pad nitride
5 Trench
10,10a,10b Insulation collar
20,20a,20b Conductive filling (e.g. polysilicon)
15a,15b Buried contact
16a,16b Insulation region
G1,G2 Trench
GK1,GK2 Trench capacitor
30,30a,30b Capacitor dielectric
S1,S2,S3 Source region
D1,D2 Drain region
K2 Channel region
WL,WL1,WL2,WL3 Word line
GS1,GS2,GS3 Gate stack
GI1,GI2,GI3 Gate insulator
I Insulation layer
F Minimum length unit
BLK Bit line contact
BL Bit line
DT Trench
AA Active region
STI Insulation region (shallow trench isolation)
UC Area unit cell
KS,KS1,KS2 Contact region
IS,IS1,IS2 Insulation region
21 Polysilicon liner
22,40 Silicon nitride liner
60 Silicon oxide mask
23 Polysilicon filling
25 TiN filling
65 Silicon oxide filling
50 polysilicon filling
40′ silicon nitride spacer
21′ polysilicon spacer
stt sti trench depth
O opening

1. Method for fabricating a trench capacitor with an insulation collar in a substrate, which is electrically connected to the substrate on one side via a buried contact, in particular for a semiconductor memory cell with a planar selection transistor that is provided in the substrate and connected via the buried contact having the steps of:
(a) providing a trench in the substrate using a hard mask with a corresponding mask opening;
(b) providing a capacitor dielectric in the lower and central trench region, the insulation collar in the central and upper trench region and an electrically conductive filling as far as the top side of the insulation collar;
(c) providing a spacer made of a conductive material above the insulation collar in electrical contact with the substrate;
(d) filling completely the trench with a filling material above the liner layer;
(e) carrying out an STI trench fabrication process;
(f) removing the filling material and sinking the electrically conductive filling to below the top side of the insulation collar;
(g) providing a metallic filling in the trench and etching back the metallic filling as far as the top side of the spacer and
(h) providing an insulation region on one side and a contact region on a different side with respect to the substrate above the insulation collar by partly removing the spacer.

2. Method according to claim 1, wherein a liner layer is provided in the trench before the trench is filled, and the liner layer is likewise removed after the removal of the filling material.

3. Method according to claim 1, wherein, after the metallic filling has been etched back, an insulation cover is provided in the upper trench region at least as far as the top side of the substrate.

4. Method according to claim 2, wherein the spacer is provided after the removal of the filling material and, before the spacer is provided, a further spacer is formed on the trench walls above the insulation collar, which serves as a mask in the course of sinking the electrically conductive filling and is then removed.

5. Method according to claim 1, wherein the following steps are carried out for partly removing the spacer:
(a) providing a liner layer in the trench;
(b) providing a mask on the liner layer in the trench, which has an opening above the spacer region to be removed; and
(c) perforating the liner layer and selectively removing the spacer region to be removed using the mask.

6. Method according to claim 1, wherein the spacer is provided by depositing a liner layer made of the conductive material and carrying out a spacer etching.

7. Method according to claim 1 wherein the spacer is provided before the trench is filled.

8. Method according to claim 1, wherein the metallic filling comprises TiN or W or WSix or TaN or WN or HfN.

9. Method according to claim 1. wherein the conductive material is polysilicon.

10. Method according claim 1, wherein the liner layer comprises silicon nitride.
